(19) United States
(12) Patent Application Publication
(10) Pub. No.: US 2020/0292131 A1
(43) Pub. Date: Sep. 17, 2020

(54) FLUID SUPPLY APPARATUS

(71) Applicant: KCTECH CO., LTD., Anseong-si (KR)

(72) Inventor: Dong Min Kim, Seoul (KR)

(21) Appl. No.: 16/748,854

(22) Filed: Jan. 22, 2020

(30) Foreign Application Priority Data
Mar. 15, 2019 (KR) 10-2019-0030095

(51) Int. Cl. F17C 7/00; H05B 1/02; H01L 21/67

(52) U.S. Cl. CPC F17C 7/00; H05B 1/0233; H05B 1/0244; H01L 21/67017; F17C 2270/0518; F17C 2227/0302; F17C 2223/0115; F17C 2221/013; F17C 2205/0352

(57) ABSTRACT

The present invention relates to a fluid supply apparatus, that is, a fluid supply apparatus configured to supply a fluid having a predetermined temperature to a chamber. The fluid supply apparatus according to the present invention includes a supply line through which a fluid to be supplied to a chamber flows, at least one bypass line which branches off from a first branch portion of the supply line and connected to a second branch portion of the supply line, and a heater configured to heat the fluid flowing through the bypass line.

### CROSS-REFERENCE TO RELATED APPLICATION

This application claims priority to and the benefit of Korean Patent Application No. 10-2019-0030095, filed on Mar. 15, 2019, the disclosure of which is incorporated herein by reference in its entirety.

### BACKGROUND

### 1. Field of the Invention

The present invention relates to a fluid supply apparatus, that is, a fluid supply apparatus configured to supply a fluid having a predetermined temperature to a chamber.

### 2. Discussion of Related Art

With the recent rapid development of information and telecommunication fields and popularization of information media such as computers, semiconductor devices are also rapidly developing. In addition, from a functional viewpoint thereof, various methods are being researched and developed to reduce a size of an individual element formed on a substrate according to a trend that elements of a semiconductor device are highly integrated and also to maximize functions of the elements.

Generally, semiconductor elements are manufactured by repeatedly performing a plurality of processes, such as lithography, deposition, etching, coating and developing of a photoresist, cleaning, and drying processes, on a substrate.

Each of the processes is performed using a process fluid suitable to an objective of the process and requires a suitable process environment.

Generally, a chamber or bath in which a corresponding environment is formed accommodates a substrate to perform each of the processes, and the chamber sealed to prevent introduction of external particles may accommodate the substrate therein to perform the processes.

Particles, such as metal impurities and organic matters, remain on the substrate on which each of the processes is performed, and such contaminants lead to process defects of the substrate and have a negative effect on product yield and reliability.

Accordingly, cleaning and drying processes, which are repeatedly performed to remove the particles whenever the processes are completed, are very important.

The cleaning process is classified as a wet cleaning process or a dry cleaning process, and the wet cleaning process among the wet cleaning process and the dry cleaning process is widely used in a semiconductor manufacturing field.

The wet cleaning process is a method of consecutively removing the contaminants using chemical materials suitable to the contaminants for each process, and large amounts of acid and alkaline solutions are used to remove the contaminants remaining on the substrate.

In the dry etching process, a supercritical fluid is widely used. Particularly, since a design rule of a semiconductor element is continuously decreased so that a fine pattern is mainly formed and an aspect ratio of the pattern is rapidly increased, a supercritical fluid is used as a solution to a pattern leaning phenomenon that occurs when a chemical liquid is dried after a wet process such as the etching process, the cleaning process, or the like.

A material reaches a supercritical state in which the material is indistinguishable between a gas and a liquid above limits of a certain high temperature and a predetermined high pressure which are called critical points, and the material in the state is called a supercritical fluid.

The supercritical fluid has a property that a change in a molecular density is big. A molecular density of the supercritical fluid is close to that of a liquid, but a viscosity thereof is low and close to that of a gas. In addition, the supercritical fluid has unique properties of quickly diffusing like a gas so that thermal conductivity thereof is high as much as that of water but is used as a solvent like a liquid so that a concentration of the solvent is high around a solute, and the supercritical fluid is not affected by surface tension. Accordingly, the supercritical fluid is used in various fields because the supercritical fluid is very useful for chemical reactions and has a high ability to extract and separate certain components from a mixture, and particularly, supercritical carbon dioxide, which is a material that has a critical temperature close to room temperature and is a nonpolar material, is highly utilized.

Accordingly, a study is being actively conducted for a fluid supply apparatus configured to maintain a temperature of a fluid greater than or equal to a suitable temperature, that is, a critical temperature, wherein the fluid flows through a supply line to be supplied to a chamber in a supercritical state.

A fluid supply apparatus configured to supply a fluid to a substrate process chamber according to the conventional technology will be described with reference to FIG. 1.

The fluid supply apparatus according to the conventional technology includes a fluid tank 10 which temporarily stores a fluid to be supplied to a substrate process chamber 30, and a supply line 20 which connects the chamber 30 and the fluid tank 10. The fluid tank 10 includes a fluid tank heater 11 which heats the fluid in the fluid tank 10, and the supply line 20 includes a supply line heater 21 which heats the fluid flowing through the supply line 20 and a supply line pump 22 which pumps the fluid such that the fluid flows toward the chamber 30.

Carbon dioxide in a gas or liquid state is introduced into and sorted in the fluid tank 10, and the carbon dioxide is heated by the fluid tank heater 11 and reaches a supercritical state.

A temperature of the supercritical carbon dioxide is decreased when the supercritical carbon dioxide flows to the chamber 30 through the supply line 20, and the supercritical carbon dioxide is heated by the supply line heater 21 to restore the decreased temperature and is supplied to the chamber 30.

In this case, since a substrate treatment process is performed in the chamber 30 and the carbon dioxide is continuously supplied to the chamber 30, the carbon dioxide stored in the fluid tank 10 may be introduced into the supply line 20 in a state in which the carbon dioxide is not sufficiently heated.

Although the carbon dioxide is heated by the supply line heater 21, the carbon dioxide in a liquid or gas state of which a temperature does not meet a critical temperature may be introduced into the chamber 30, or the carbon dioxide in an unstable supercritical state of which a temperature barely meets the critical temperature may be introduced into the chamber 30, and thus a phase thereof may be changed into a liquid or gas state.

Accordingly, as the substrate treatment processes are progressed, process defects may occur because drying processes using the supercritical carbon dioxide are not smoothly performed.

An example of the related art of the substrate process chamber is disclosed in Korean Patent Registration No. 10-1336727.

### SUMMARY OF THE INVENTION

The present invention is directed to providing a fluid supply apparatus configured to supply a fluid having a predetermined temperature to a chamber.

According to an aspect of the present invention, there is provided a fluid supply apparatus including a supply line through which a fluid to be supplied to a chamber flows, at least one bypass line which branches off from a first branch portion of the supply line and is connected to a second branch portion of the supply line, and a heater configured to heat the fluid flowing through the bypass line.

The first branch portion may include a path switch configured to switch a flow path of the fluid such that the fluid selectively flows through the supply line or the bypass line.

The path switch may include a supply valve configured to open or close the supply line and a bypass valve configured to open or close the bypass line or may include a three way valve configured to simultaneously open or close the supply line and the bypass line connected from the first branch portion to the chamber.

In addition, a thermometer configured to measure a temperature of a fluid flowing through the supply line may be provided, and the thermometer may include a first measurement unit configured to measure a temperature of the fluid flowing toward the first branch portion and a second measurement unit configured to measure a temperature of the fluid flowing from the second branch portion toward the chamber.

In this case, a controller may control the path switch to switch the flow path of the fluid according to a first temperature measurement value of the fluid measured by the first measurement unit.

In addition, the controller may compare a second temperature measurement value of the fluid measured by the second measurement unit with a preset second set value to control a heating temperature of the heater.

In addition, a plurality of temperature control units each including the bypass line, the heater, the first measurement unit, and the path switch may be provided in series on the supply line, and the second measurement unit may measure a temperature of the fluid flowing from a rear end of the plurality of temperature control units toward the chamber.

In this case, the controller may compare a second temperature measurement value of the fluid measured by the second measurement unit with a preset second set value to adjust a heating temperature of at least one of a plurality of heaters included in the plurality of temperature control units.

In addition, the fluid supply apparatus according to the present invention may further include a fluid tank which stores a predetermined amount of the fluid and supplies the fluid to the supply line, a fluid tank heater configured to heat the fluid in the fluid tank, and a supply line heater configured to heat the fluid flowing through the supply line.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a schematic view illustrating a fluid supply apparatus according to a conventional technology;

FIG. 2 is a schematic view illustrating a fluid supply apparatus according to a first embodiment of the present invention;

FIG. 3 is a schematic view illustrating a fluid supply apparatus according to a second embodiment of the present invention;

FIG. 4 is a schematic view illustrating a fluid supply apparatus according to a third embodiment of the present invention;

FIG. 5 is a schematic view illustrating a fluid supply apparatus according to a fourth embodiment of the present invention;

FIG. 6 is a schematic view illustrating a fluid supply apparatus according to a fifth embodiment of the present invention; and

FIG. 7 is a schematic view illustrating a fluid supply apparatus according to a sixth embodiment of the present invention.

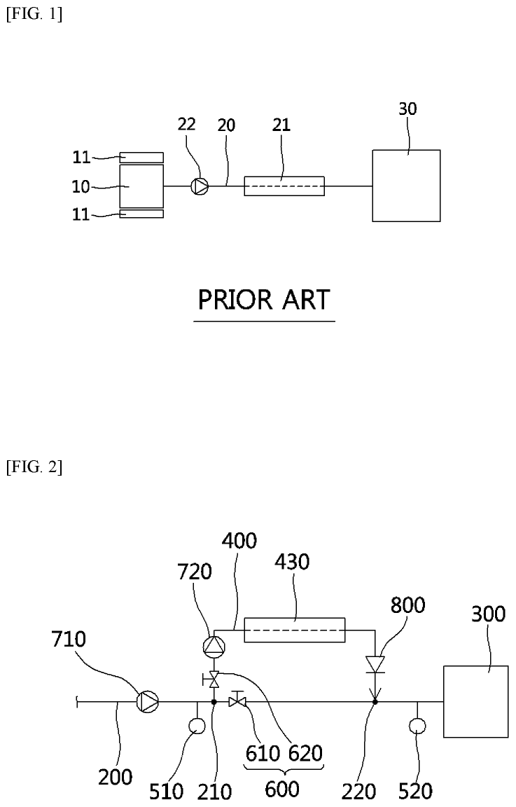

### DETAILED DESCRIPTION OF EXEMPLARY EMBODIMENTS

Configurations and operations of a fluid supply apparatus according to the present invention will be described in detail with reference to the accompanying drawings.

Here, detailed descriptions of the contents of the present invention which are redundant with those of the described conventional technology will be omitted, and newly added contents according to the present invention will be mainly described.

In addition, in the detailed descriptions of the present invention, a “front end” is referred to as “one end (a right end in the drawing)” in a direction opposite to a direction in which a fluid moves, and a “rear end” is referred to as “one end (a left end in the drawing)” in a direction in which the fluid flows.

A fluid supply apparatus according to a first embodiment of the present invention will be described with reference to FIG. 2. The fluid supply apparatus according to the first embodiment of the present invention includes a supply line 200 through which a fluid to be supplied to the chamber 300 flows, at least one bypass line 400 which branches off from a first branch portion 210 of the supply line and is connected to a second branch portion 220 of the supply line, and a heater 430 configured to heat the fluid flowing through the bypass line 400.

The chamber 300 may be a substrate process chamber configured to accommodate and process a semiconductor substrate, and the fluid may be a process fluid which is supplied to the chamber 300 to process the substrate.

The process fluid may be a cleaner to remove contaminants on the substrate, and a plurality of different cleaners may be used according to kinds of contaminants to be processed.

For example, an organic solvent and nitrogen (N2) gas may be used to remove a resist. In addition, water, hydrogen fluoride (HF), isopropyl alcohol (IPA), and nitrogen (N2) gas may be used to remove silicon oxide (SiO). In addition, hydrochloric acid (HCl), ozone (O₃), and nitrogen (N2) gas may be used to remove a metal. In addition, ozone (O₃) and nitrogen (N2) gas may be used to remove an organic material except for the resist. In addition, an ammonia peroxide mixture (APM), nitrogen (N2) gas, or argon (Ar) gas may be used to remove other particles. In addition, water, isopropyl alcohol (IPA), and nitrogen (N2) gas may be used to remove ions of fluorine (F), chlorine (Cl), and ammonia (NH₄).

In addition, the process fluid may be a drying agent to dry the substrate which is supplied to the chamber 300 and on which a cleaning process is performed by the cleaner.

The drying agent is provided to correspond to a kind of the cleaner supplied to the substrate, and a supercritical fluid of carbon dioxide (CO₂), water (H₂O), methane (CH₄), ethane (C₂H₆), propane (C₃H₈), ethylene (C₂H₄), propylene (C₂H₂), methanol (C₂H₃OH), ethanol (C₂H₅OH), sulfur hexafluoride (SF₆), acetone (C₃H₈O), or the like may be used as the drying agent.

A temperature of the process fluid is set to a suitable temperature, and the process fluid is supplied to the chamber 300 to perform a cleaning or drying process for the substrate.

As an example, in a case in which a drying process using supercritical carbon dioxide as a process fluid is performed in the chamber 300, the process fluid is set to a temperature greater than or equal to a critical temperature and supplied to the chamber 300 in a supercritical state.

According to the first embodiment, the second branch portion 220 is formed behind the first branch portion 210, the fluid flows through only the supply line 200 and is supplied to the chamber 300, or the fluid flows through the first branch portion 210 and the bypass line 400, is heated by the heater 430, is re-introduced into the supply line 200 thorough the second branch portion 220, and is supplied to the chamber 300.

The heater 430 may be a coil type heater which is spirally wound along a circumference of the bypass line 400.

The first branch portion 210 includes a path switch 600 configured to selectively switch a flow path of the fluid such that the fluid selectively flows through the supply line 200 or the bypass line 400.

The path switch 600 may include a supply valve 610 configured to open or close a rear end of the first branch portion 210 on the supply line 200, and a bypass valve 620 configured to open or close the bypass line 400.

When the supply valve 610 is opened and the bypass valve 620 is closed, the fluid flows through only the supply line 200 and is supplied to the chamber 300.

When the supply valve 610 is closed and the bypass valve 620 is opened, the fluid flows through the first branch portion 210 and the bypass line 400, is introduced into the supply line 200 through the second branch portion 220, and is supplied to the chamber 300.

A supply line pump 710 which pumps the fluid such that the fluid flows toward the chamber 300 may be provided on the supply line 200, and a bypass pump 720 which pumps the fluid such that the fluid flows from the first branch portion 210 toward the second branch portion 220 may be further provided on the bypass line 400.

In this case, the path switch 600, the supply line pump 710, and the bypass pump 720 may be organically controlled by a controller (not shown).

In addition, a backflow preventer 800 configured to prevent a backflow of the fluid flowing through the bypass line 400 may be provided on the bypass line 400, and the backflow preventer 800 may be provided with a check valve.

In addition, thermometers 510 and 520 configured to measure a temperature of the process fluid flowing through the supply line 200 are provided on the supply line 200.

The thermometers 510 and 520 include a first measurement unit 510 which is provided on the first branch portion 210 or in front of the first branch portion 210 and measures a temperature of the fluid flowing toward the first branch portion 210.

A first temperature measurement value which is a measurement value of the temperature of the fluid measured by the first measurement unit 510 may be transmitted to the controller, and the controller may compare a first set value which is a preset value of a temperature having the first temperature measurement value to control the path switch 600 according to the result.

In this case, since the fluid introduced into the bypass line 400 is heated by the heater 430, the path switch 600 is controlled to control whether the fluid passes through the bypass line 400 so as to control whether the fluid is heated.

According to one embodiment, the first set value may be set to a lowest value of a temperature required for the fluid. In this case, the controller opens the supply valve 610 and closes the bypass valve 620 when the first temperature measurement value is greater than or equal to the first set value to control the fluid to be directly supplied to the chamber 300 through the supply line 200.

In addition, the controller controls the supply valve 610 to be closed and the bypass valve 620 to be opened when the first temperature measurement value is less than the first set value to control the fluid to flow through the bypass line 400 and to be heated by the heater 430 so that temperature suitability of the fluid supplied to the chamber 300 can be improved.

In addition, the thermometers 510 and 520 may further include a second measurement unit 520 which is provided in front of the chamber 300 on the supply line 200 and configured to measure a temperature of the fluid that is finally introduced into the chamber 300.

The second measurement unit 520 may check a temperature of the fluid flowing from the second branch portion 220 to the chamber 300.

The controller compares a second temperature measurement value which is a temperature measurement value of the fluid measured by the second measurement unit 520 and a second set value which is a preset value of a temperature to control a heating temperature of the heater.

In this case, since a temperature loss occurs which is proportional to a time period and a distance while the fluid flows, the first set value of a temperature is set to be greater than or equal to the second set value by considering the flowing distance of the fluid of which a temperature is sequentially measured by the first measurement unit 510 and the second measurement unit 520.

As an example, in a case in which the supercritical carbon dioxide is supplied as the process fluid to the chamber 300 in which a drying process is performed, the second set value of a temperature may be set to be greater than or equal to a value of a supercritical temperature, and the first set value of a temperature may be set to be greater than the second set value to maintain the carbon dioxide in a supercritical state and to supply the carbon dioxide to the chamber 300.

In addition, in a case in which the second temperature measurement value is less than the second set value, the controller controls the heater to further increase a heating temperature.

Accordingly, since the fluid flowing through the bypass line 400 is heated to have a higher temperature, and the second temperature measurement value of the fluid flowing toward the chamber 300 meets the second set value, temperature suitability of the fluid can be improved.

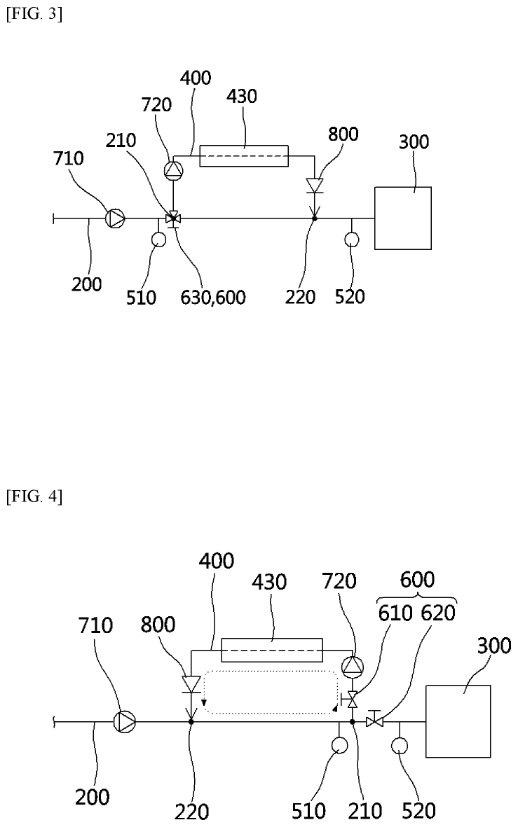

A fluid supply apparatus according to a second embodiment of the present invention will be described with reference to FIG. 3. A configuration of the fluid supply apparatus according to the second embodiment of the present invention is the same as the configuration of the fluid supply apparatus according to the first embodiment except that a path switch provided in a first branch portion 210 includes a three way valve 630.

The three way valve 630 opens a rear end of the first branch portion 210 on a supply line 200 and simultaneously closes a bypass line 400 or, conversely, closes the rear end of the first branch portion 210 on the supply line 200 and simultaneously opens the bypass line 400 to selectively switch a flow path of a fluid flowing in the supply line 200 so that a configuration of the path switch 600 can be simplified and the flow path of the fluid can also be easily switched.

A fluid supply apparatus according to a third embodiment of the present invention will be described with reference to FIG. 4. A configuration of the fluid supply apparatus according to the third embodiment of the present invention is the same as the configuration of the fluid supply apparatus according to the first embodiment except that a first branch portion 210 is formed behind a second branch portion 220.

According to the third embodiment, a circulation path is formed that includes a supply line 200, in which the second branch portion 220 is connected to the first branch portion 210, and a bypass line 400.

Accordingly, in a case in which a first temperature measurement value of a first measurement unit 510 is less than a first set value, a fluid flows through the first branch portion 210 and the bypass line 400, is heated, is introduced into the supply line 200 through the second branch portion 220, and flows toward the first branch portion 210, and thus the fluid circulates along the circulation path.

In this case, the first measurement unit 510 measures a temperature of the fluid which circulates and returns along the circulation path, and in a case in which the measured first temperature measurement value is less than the first set value, the fluid circulates in the circulation path again and is heated so that temperature suitability of the fluid can be improved.

To this end, a controller may control path switches to maintain a state in which the supply line is closed and the bypass line is opened until the first temperature measurement value meets a value of a temperature greater than or equal to the first set value.

A fluid supply apparatus according to a fourth embodiment of the present invention will be described with reference to FIG. 5. A configuration of the fluid supply apparatus according to the fourth embodiment of the present invention is the same as the configuration of the fluid supply apparatus according to the first embodiment except that sets of temperature control units U1 and U2 respectively include bypass lines 410 and 420, heaters 431 and 432, first measurement units 511 and 512, and path switches 640 and 650 and the plurality of sets of the temperature control units U1 and U2 are provided on a supply line 200 in series.

In addition, a second measurement unit 520 measures a temperature of a fluid flowing from a rear end of the plurality of sets of the temperature control units U1 and U2 to a chamber 300.

As an example of the third embodiment, an example of the fluid supply apparatus including two sets of temperature control units U1 and U2, that is, a first temperature control unit U1 and a second temperature control unit U2, which are sequentially provided on the supply line 200, will be described.

Referring to FIG. 5, the bypass line 410 of the first temperature control unit U1 branches off from a third branch portion 263 of the supply line 200 and is connected to a fourth branch portion 264.

The first measurement unit 511 of the first temperature control unit U1 measures a temperature of the fluid flowing toward the third branch portion 263, and a controller compares the measurement value of the temperature of the fluid having a first set value of the first measurement unit 511 of the first temperature control unit U1 to control the path switch 640 of the first temperature control unit U1.

Accordingly, the fluid flowing toward the third branch portion 263 flows through the supply line 200 to the fourth branch portion 264 or flows through the bypass line 410 of the first temperature control unit U1, is heated by the heater 431, and flows to the fourth branch portion 264.

In addition, the bypass line 420 of the second temperature control unit U2 branches off from a fifth branch portion 265 of the supply line 200 and is connected to a sixth branch portion 266.

The first measurement unit 512 of the second temperature control unit U2 measures a temperature of the fluid flowing from the fourth branch portion 264 toward the fifth branch portion 265 and compares the measurement value of a temperature of the fluid having a first set value of the first measurement unit 512 of the second temperature control unit U2 to control the path switch 650 of the second temperature control unit U2.

Accordingly, the fluid flowing toward the fifth branch portion 265 flows to the sixth branch portion 266 through the supply line 200 or flows through the bypass line 420 of the second temperature control unit U2, is heated by the heater 432, and flows to the fourth branch portion 264.

In this case, the first set value of a temperature set in the first measurement unit 511 of the first temperature control unit U1 and the first set value of a temperature set in the first measurement unit 512 of the second temperature control unit U2 are set to be greater than a second set value by considering a flow distance of the fluid.

In addition, the first set value of a temperature set in the first measurement unit 511 of the first temperature control unit U1 may be set to be greater than the first set value set in the first measurement unit 512 of the second temperature control unit U2.

In addition, in a case in which the second temperature measurement value is less than the second set value, the controller adjusts a heating temperature of the heater 431 of the first temperature control unit U1 or the heater 432 of the second temperature control unit U2 to be further increased.

Accordingly, the second temperature measurement value of the fluid, which flows to the chamber 300 through the bypass line 410 of the first temperature control unit U1 or through the bypass line 420 of the second temperature control unit U2, meets the second set value, and thus temperature suitability of the fluid can be improved.

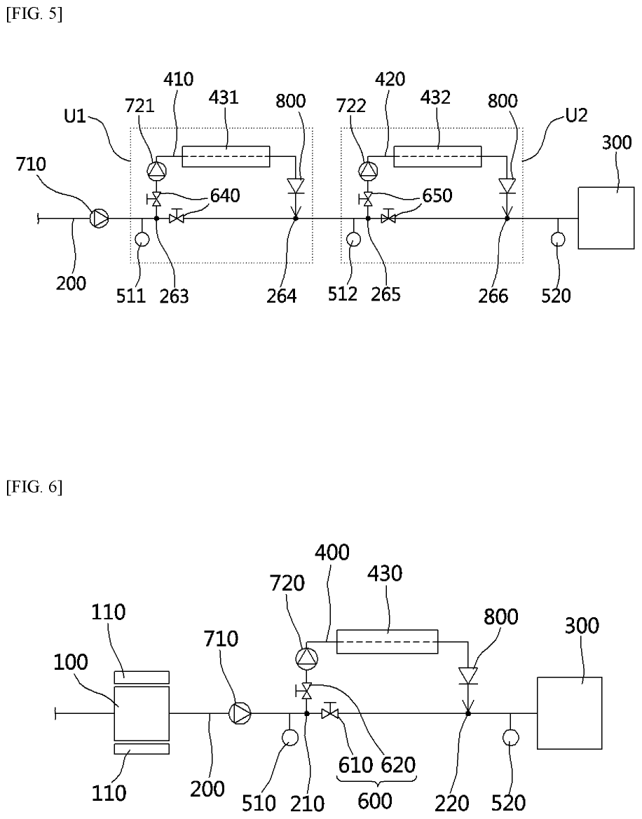

A fluid supply apparatus according to a fifth embodiment of the present invention will be described with reference to FIG. 6. A configuration of the fluid supply apparatus according to the fifth embodiment of the present invention is the same as the configuration of the fluid supply apparatus according to the first embodiment except that a fluid tank 100 which stores a predetermined amount of a fluid and supplies the predetermined amount of the fluid to a supply line 200 and a fluid tank heater 110 configured to heat the fluid in the fluid tank 100 are included therein.

The fluid tank heater 110 may be provided to heat the fluid in the fluid tank 100 by heating at least one side surface of the fluid tank 100.

Accordingly, the fluid may be heated first by the fluid tank heater 110 in a state in which the fluid is stored in the fluid tank 100 and supplied to a supply line 200, and since the fluid can be stably heated when compared to a method of heating a flowing fluid, temperature suitability of the fluid can be improved.

In addition, when a first temperature measurement value measured by a first measurement unit 510 does not meet a preset first set value, a controller controls the fluid to flow through a first branch portion 210 toward a bypass line 400, be heated secondarily by a heater 430, and be introduced into the supply line 200 through a second branch portion 220 so that temperature suitability can be improved.

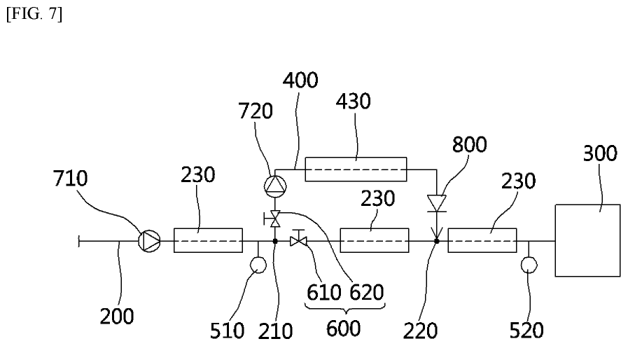

A fluid supply apparatus according to a sixth embodiment of the present invention will be described with reference to FIG. 7. A configuration of the fluid supply apparatus according to the sixth embodiment of the present invention is the same as the configuration of the fluid supply apparatus according to the first embodiment except that at least one supply line heater 230 configured to heat a fluid flowing through a supply line 200 is included.

The supply line heater 230 may be a coil type heater which is spirally wound along a circumference of the supply line 200.

The supply line heater 230 may serve a complementary function to a heater 430 to improve temperature suitability of the fluid.

As described above, in the fluid supply apparatus according to the present invention, the bypass line 400 is connected to the supply line 200, the heater 430 is provided on the bypass line 400, and the flow path of the fluid is switched to select whether or not to heat the fluid, and thus temperature suitability of the fluid supplied to the chamber 300 can be improved.

In addition, the thermometers 510 and 520 configured to measure a temperature of the fluid flowing through the supply line 200 are provided, and the controller organically controls the path switch 600 configured to switch the flow path of the fluid according to temperature measurement values of the thermometers 510 and 520, and thus user convenience can be improved.

In addition, since the first measurement unit configured to measure a temperature of the fluid flowing toward the first branch portion 210 is provided to switch the flow path of the fluid according to a first temperature measurement value so as to select whether or not to heat the fluid, temperature suitability of the fluid supplied to a chamber 300 can be improved.

In addition, since the path switch 600 includes the three way valve 630, a structure of the path switch 600 can be simplified and the flow path of the fluid can be simply switched.

In addition, since the second measurement unit configured to measure a temperature of the fluid flowing toward the chamber 300 is provided to adjust a heating temperature of the heater 430 according to a second temperature measurement value, temperature suitability of the fluid supplied to the chamber 300 can be improved.

In addition, since the second branch portion 220 is formed behind the first branch portion 210 to repeatedly circulate the fluid along the circulation path including the bypass line 400 and to repeatedly heat the fluid, temperature suitability of the fluid can be improved.

In addition, the plurality of temperature control units U1 and U2 are provided on the supply line 200, and the fluid flows through the plurality of bypass lines 410 and 420 and is heated a plurality of times, and thus temperature suitability of the fluid can be improved.

In addition, a predetermined amount of the fluid is stored in the fluid tank 100, is heated first by the fluid tank heater 110, and is supplied to the supply line 200, and thus temperature suitability of the fluid can be improved.

In addition, since the supply line heater 230 configured to heat the fluid flowing through the supply line 200 is provided to serve a complementary function to the heater 430, temperature suitability of the fluid can be improved.

By using the fluid supply apparatus according to the present invention, since a fluid having a predetermined temperature is supplied to a chamber and used to perform a substrate treatment process, a process defect of a substrate due to a decrease in temperature of the fluid can be prevented.

In addition, since heating of the fluid can be selected by switching a flow path, temperature suitability of the fluid supplied to the chamber can be improved.

The present invention is not limited to the above described embodiments and may be clearly modified by those skilled in the art without departing from the technical spirit of the present invention appended in the claims, and such a modified embodiment will be included in the scope of the present invention.

What is claimed is:

1. A fluid supply apparatus comprising:
a supply line through which a fluid to be supplied to a chamber flows;
at least one bypass line which branches off from a first branch portion of the supply line and is connected to a second branch portion of the supply line; and
a heater configured to heat the fluid flowing through the bypass line.

2. The fluid supply apparatus of claim 1, further comprising a thermometer configured to measure a temperature of the fluid flowing through the supply line.

3. The fluid supply apparatus of claim 2, wherein the thermometer includes a first measurement unit configured to measure a temperature of the fluid flowing toward the first branch portion.

4. The fluid supply apparatus of claim 2, wherein the thermometer includes a second measurement unit configured to measure a temperature of the fluid flowing from the second branch portion toward the chamber.

5. The fluid supply apparatus of claim 3, wherein the first branch portion includes a path switch configured to switch a flow path of the fluid such that the fluid selectively flows in the supply line or the bypass line.

6. The fluid supply apparatus of claim 5, wherein the path switch includes:
a supply valve configured to open or close the supply line; and
a bypass valve configured to open or close the bypass line.

7. The fluid supply apparatus of claim 5, wherein the path switch includes a three way valve configured to switch the flow path of the fluid such that any one line of the supply line and the bypass line is selectively opened and the remaining one line is closed.

8. The fluid supply apparatus of claim 5, further comprising a controller configured to control the path switch.

9. The fluid supply apparatus of claim 8, wherein the controller controls the path switch according to a first temperature measurement value of the fluid measured by the first measurement unit.

10. The fluid supply apparatus of claim 9, wherein the controller:
controls the path switch to open the supply line and close the bypass line when the first temperature measurement value is greater than or equal to a preset first set value; and
controls the path switch to close the supply line and open the bypass line when the first temperature measurement value is less than the first set value.

11. The fluid supply apparatus of claim 10, wherein:
a circulation path is formed in which the first branch portion is formed behind the second branch portion so that the fluid introduced into the bypass line through the first branch portion is introduced into the supply line through the second branch portion and flows to the first branch portion; and
the controller controls the path switch to maintain a state in which the supply line is closed and the bypass line is opened until the first temperature measurement value of a temperature is greater than or equal to the first set value so that the fluid circulates along the circulation path and is repeatedly heated.

12. The fluid supply apparatus of claim 10, wherein:
the thermometer includes a second measurement unit configured to measure a temperature of the fluid flowing from the second branch portion toward the chamber; and
the controller compares a second temperature measurement value of the fluid measured by the second measurement unit having a preset second set value to adjust a heating temperature of the heater.

13. The fluid supply apparatus of claim 12, wherein the first set value of a temperature is set to be greater than the second set value.

14. The fluid supply apparatus of claim 12, wherein, when the second temperature measurement value is less than the preset second set value, the controller controls a heating temperature of the heater to be further increased.

15. The fluid supply apparatus of claim 12, wherein:
the bypass line, the heater, the first measurement unit, and the path switch form a set of a temperature control unit;
a plurality of sets of temperature control units identical to the temperature control unit are provided on the supply line;
the second measurement unit measures a temperature of the fluid flowing from a rear end of the plurality of sets of the temperature control units toward the chamber; and
the controller compares a second temperature measurement value of the fluid measured by the second measurement unit having the preset second set value to adjust a heating temperature of at least one of a plurality of heaters included in the plurality of sets of the temperature control units.

16. The fluid supply apparatus of claim 15, wherein a first set value of a temperature of the first measurement units included in each of the plurality of sets of the temperature control units is set to be greater than the second set value.

17. The fluid supply apparatus of claim 15, wherein, when the second temperature measurement value is less than the second set value, the controller controls a heating temperature of at least one of the plurality of heaters included in the plurality of sets of the temperature control units to be further increased.

18. The fluid supply apparatus of claim 1, further comprising a backflow preventer configured to prevent a backflow of the fluid flowing through the bypass line.

19. The fluid supply apparatus of claim 18, wherein the backflow preventer includes a check valve.

20. The fluid supply apparatus of claim 1, further comprising:
a fluid tank which stores a predetermined amount of the fluid and supplies the fluid to the supply line; and
a fluid tank heater configured to heat the fluid in the fluid tank.

21. The fluid supply apparatus of claim 1, further comprising at least one supply line heater configured to heat the fluid flowing through the supply line.

22. The fluid supply apparatus of claim 1, wherein the at least one bypass line includes a first bypass line and a second bypass line sequentially connected on the supply line.

23. The fluid supply apparatus of claim 1, wherein the heater includes a coil type heater which is spirally wound along a circumference of the bypass line.

24. The fluid supply apparatus of claim 20, wherein the fluid tank heater heats at least one side surface of the fluid tank to heat the fluid in the fluid tank.

25. The fluid supply apparatus of claim 21, wherein the supply line heater includes a coil type heater which is spirally wound along a circumference of the supply line.

26. The fluid supply apparatus of claim 1, wherein the fluid includes a supercritical fluid.

27. The fluid supply apparatus of claim 1, wherein the fluid includes supercritical carbon dioxide.
